(19) United States
(12) Patent Application Publication
(10) Pub. No.: US 2025/0280510 A1
(43) Pub. Date: Sep. 4, 2025

(54) SERVER CANISTER FOR LIQUID-COOLED SERVER RACKS

(71) Applicant: ZT Group Int'l, Inc., Secaucus, NJ (US)

(72) Inventors: Chen AN, Secaucus, NJ (US); Mahesh Kumar VARREY, Secaucus, NJ (US); Yuan ZHANG, Secaucus, NJ (US); Pruthvik RAGHUPATHI, Secaucus, NJ (US); Sruti CHIGULLAPALLI, Secaucus, NJ (US)

(73) Assignee: ZT Group Int'l, Inc., Secaucus, NJ (US)

(21) Appl. No.: 18/777,804

(22) Filed: Jul. 19, 2024

Related U.S. Application Data
(60) Provisional application No. 63/561,222, filed on Mar. 4, 2024.

(51) Int. Cl. H05K 7/20

(52) U.S. Cl. CPC H05K 7/20272; H05K 7/20781

(57) ABSTRACT

A canister for coupling a plurality of servers to a server rack is described herein. The canister includes an influent rigid manifold and an effluent rigid manifold that have respective pluralities of quick-disconnect (QD) fittings arranged in fixed orientations and configured to couple with corresponding QD fittings on the servers. The canister further includes an influent canister QD fitting coupled with the influent rigid manifold and configured to couple with an influent soft manifold of the server rack. The canister also includes an effluent canister QD fitting coupled with the effluent rigid manifold and configured to couple with an effluent soft manifold of the server rack. The canister is one of many canisters configured to mount to the server rack. By using multiple canisters and the soft manifolds, many liquid-cooled servers may be implemented within the server rack without necessitating high tolerance manufacturing of the manifolds.

### RELATED APPLICATIONS

This application claims the benefit of U.S. Provisional Application No. 63/561,222 filed on Mar. 4, 2024. The entire disclosure of U.S. Provisional Application No. 63/561,222 is incorporate by this reference.

### FIELD

This disclosure is directed to liquid cooling of servers within a server rack.

### BACKGROUND

Liquid cooling is quickly becoming the norm for server systems (e.g., artificial intelligence (AI), machine learning (ML), and high-performance computing (HPC) systems). Server racks often contain tens of servers (e.g., 42 1U servers in a 42u rack). To cool the servers within the server racks, the server racks often contain rigid liquid manifolds with a plurality of quick disconnect (QD) fittings mounted in fixed orientations. As the number of liquid-cooled servers (and, thus, QD fittings) increases, so does the tolerance stack up within the rigid liquid manifolds (especially in the height direction). The tolerance stack up can make the necessary connections with the servers difficult to make.

### SUMMARY

A canister for coupling a plurality of servers to a server rack is described herein. The canister includes an influent rigid manifold that has a plurality of influent rigid manifold QD fittings arranged in a fixed orientation and configured to couple with influent server QD fittings on the servers. The canister also includes an effluent rigid manifold that has a plurality of effluent rigid manifold QD fittings arranged in a fixed orientation and configured to couple with effluent server QD fittings on the servers. The canister further includes an influent canister QD fitting coupled with the influent rigid manifold and configured to couple with an influent soft manifold QD fitting of an influent soft manifold of the server rack. The canister also includes an effluent canister QD fitting coupled with the effluent rigid manifold and configured to couple with an effluent soft manifold QD fitting of an effluent soft manifold of the server rack.

A cooling system for a server rack is also described herein. The cooling system includes an influent soft manifold having a plurality of influent hoses and a plurality of influent soft manifold QD fittings at respective ends of the influent hoses. The cooling system also includes an effluent soft manifold having a plurality of effluent hoses and a plurality of effluent soft manifold QD fittings at respective ends of the effluent hoses. The cooling system further includes a plurality of the canisters described above.

A server rack is also described herein. The server rack includes a server rack frame and the cooling system described above. The canisters are configured to mount to the server rack frame.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 illustrates an example of a server rack with a cooling system including canisters in accordance with this disclosure.

FIG. 2 illustrates an example of an influent soft manifold in accordance with this disclosure.

FIG. 3 illustrates an example of a canister mounted to a server frame in accordance with this disclosure.

FIG. 4 illustrates an example of a configuration of canisters within a rack in accordance with this disclosure.

FIG. 5 illustrates an example of an influent rigid manifold, influent canister hose, and influent canister QD fitting in accordance with this disclosure.

FIG. 6 illustrates an example of mounting a canister to a server frame in accordance with this disclosure.

FIG. 7 illustrates an example of mounting a server to a canister that is mounted to a server frame in accordance with this disclosure.

### DETAILED DESCRIPTION

### Overview

Liquid cooling of servers within a server rack is often facilitated via rigid manifolds that are made of welded stainless-steel tubes with QD fittings attached to branches of the manifolds. It can be difficult to manufacture such manifolds for use with server racks configured to accept large numbers of servers. For example, tolerance stack-up in a vertical direction can cause fluid connections to be difficult to make and/or to be unreliable (e.g., leak).

Described herein is a canister for coupling a plurality of servers to a server rack. The canister includes an influent rigid manifold and an effluent rigid manifold that have respective pluralities of quick-disconnect (QD) fittings arranged in fixed orientations and configured to couple with corresponding QD fittings on the servers. The canister further includes an influent canister QD fitting coupled with the influent rigid manifold and configured to couple with an influent soft manifold of the server rack. The canister also includes an effluent canister QD fitting coupled with the effluent rigid manifold and configured to couple with an effluent soft manifold of the server rack. The canister is one of many canisters configured to mount to the server rack.

By using multiple canisters and the soft manifolds, many liquid-cooled servers may be implemented within the server rack without requiring high tolerance manufacturing. Tolerance stack-up can be mitigated because each of the rigid manifolds only services a subset of the servers of the rack.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

### Example Server Rack

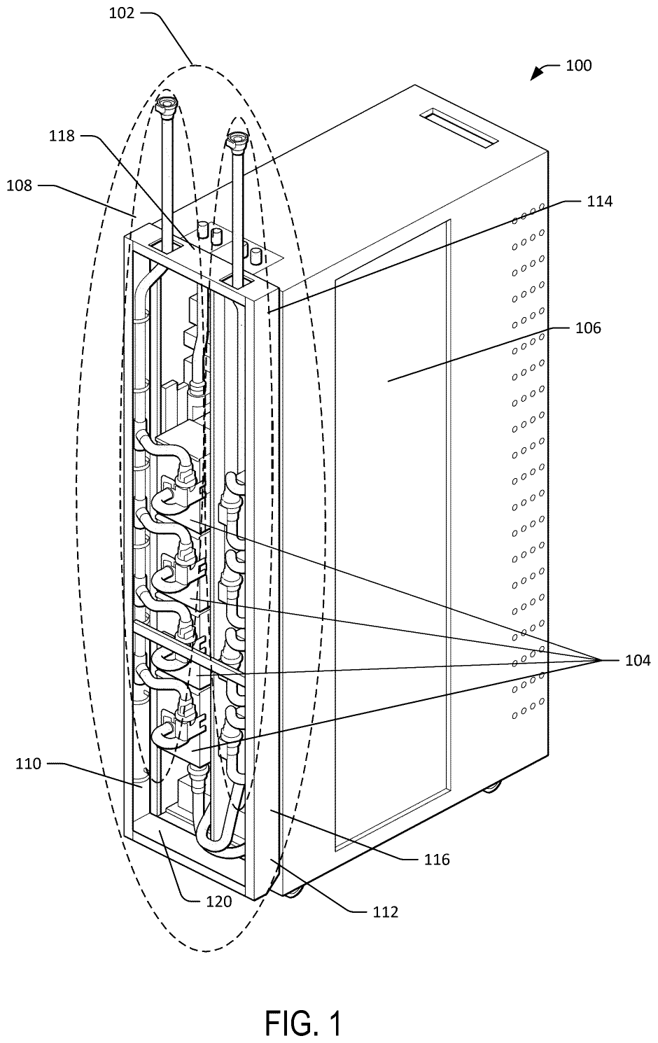

FIG. 1 illustrates an example of a server rack 100 incorporating a cooling system 102 utilizing canisters 104. The cooling system 102 may have various components thereof attached to a server rack frame 106. The server rack frame 106 may be a conventional server rack. Thus, the server rack 100 may comprise a conventional server rack with the cooling system 102 attached thereto.

In the illustrated example, the cooling system 102 contains four of the canisters 104 that are similar to each other. For example, the cooling system 102 may be configured to interface with 12 servers with each canister 104 configured to accept three of them. It should be noted that a three-server rigid manifold is much easier to manufacture within tolerance than a 12 server one. The canisters 104 are configured to couple respective pluralities of servers to the server rack frame 106. For example, each canister 104 may be configured to couple three or more servers to the server rack frame 106.

The cooling system 102 may contain any configuration and number of canisters 104 without departing from the scope of this disclosure. For example, the canisters 104 may all be similar (e.g., configured to couple a same number/size of server) or one or more of the canisters 104 may be different from the others (e.g., configured to couple a different number/size of server). Each of the canisters 104 may be configured to accept either 19-inch or 21-inch servers, for example.

Feeding the canisters 104 is an influent soft manifold 108. The influent soft manifold 108 is configured to receive cooling liquid from a source (e.g., infrastructure cooling system), split the cooling liquid into a plurality of influent flows (e.g., via branches), and provide the influent flows to the canisters 104. The influent soft manifold 108 may be coupled with a left side 110 of a soft manifold frame 112. The soft manifold frame 112 may be attached to the server rack frame 106 or be a part of the server rack frame 106.

Receiving the cooling liquid from the canisters 104 is an effluent soft manifold 114. The effluent soft manifold 114 is configured to receive effluent flows from the canisters 104 (e.g., after passing through the servers), combine the effluent flows, and provide the cooling fluid to a sink (e.g., the infrastructure cooling system). The effluent soft manifold 114 may be coupled with a right side 116 of the soft manifold frame 112. The soft manifold frame 112 may include a top 118 and/or a bottom 120 connecting the left side 110 and the right side 116.

The orientation of the influent and effluent sides may vary without departing from the scope of this disclosure. For example, the influent soft manifold 108 and the effluent soft manifold 114 may be switched (e.g., cooling fluid goes from right to left instead of left to right). Furthermore, although the connections to the influent and effluent soft manifolds are on top of the server 100, either or both of them may come out one of the sides or the bottom of the server 100.

### Example Influent Soft Manifold

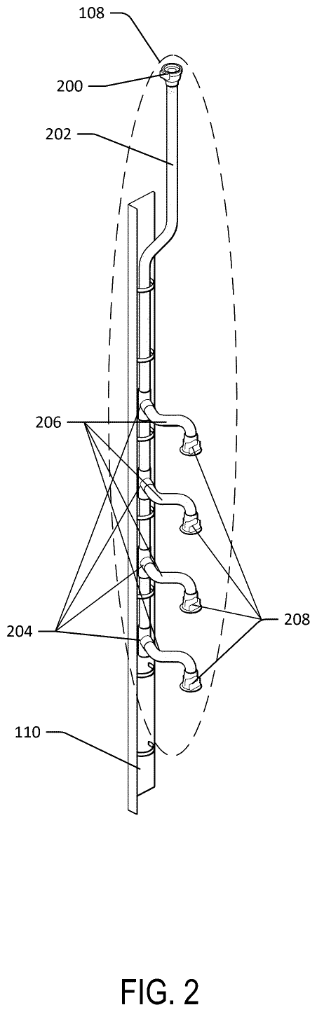

FIG. 2 illustrates an example of the influent soft manifold 108 coupled with the left side 110 of the soft manifold frame 112. To access and/or service the influent soft manifold 108, the top 118 and the bottom 120 of the soft manifold frame 112 may be removed such that the influent soft manifold 108 and the left side 110 may be removed from the server rack 100. The effluent soft manifold 114 may be removed similarly.

The influent soft manifold 108 contains an influent feeder QD fitting 200 that is configured to attach to a cooling liquid supply (e.g., from an infrastructure cooling system). Attached to the influent feeder QD fitting 200 is an influent feeder 202. The influent feeder 202 is configured to supply a manifold portion of the influent soft manifold 108 with the cooling liquid. The influent feeder 202 is coupled with a first of a plurality of influent branch fittings 204. The influent branch fittings 204 are configured to supply the cooling liquid to a plurality of influent hoses 206. For example, the influent branch fittings 204 may be tees (pipe or tubing tees). In some implementations, an influent branch fitting 204 furthest from the influent feeder 202 may be an ell. In other implementations, the influent hoses 206 may all be coupled with the influent feeder 202 (e.g., in a multiple (four in the illustrated example)-to-one fitting). At the ends of the influent hoses 206 are influent soft manifold quick-disconnect (QD) fittings 208. The influent soft manifold QD fittings 208 are configured to connect with influent canister QD fittings on the canisters 104.

QD fittings as described herein may be any type of fluid connector. A QD fitting may be a simple hose connection (e.g., barb fitting or tubing connector) or a mating connector (e.g., blind mate, push-to-connect, twist lock, or sanitary). The types of QD fittings may vary within the system (e.g., different types for the various connections) without departing from the scope of this disclosure.

The influent feeder 202 and fluid connections between the influent branch fittings 204 may be soft (e.g., flexible) or rigid. The influent hoses 206, however, are configured to be soft such that they can move relative to the rest of the influent soft manifold 108. Soft in the context of this disclosure means the ability to deform, at least slightly, without undue force and/or without breaking. For example, the influent hoses 206 may be rubber or flexible plastic hose or tubing. The rest of the influent soft manifold 108 may be formed of rigid pipe or tubing (e.g., metal or plastic), flexible hose or tubing, or some combination thereof. In some implementations, the influent hoses 206 may be attached to a rigid manifold (e.g., a rigid structure of tubing or piping) of the influent soft manifold 108. Regardless of how it is constructed, the influent soft manifold 108 is configured to allow the influent soft manifold QD fittings 208 to move relative to one another.

### Example Canister

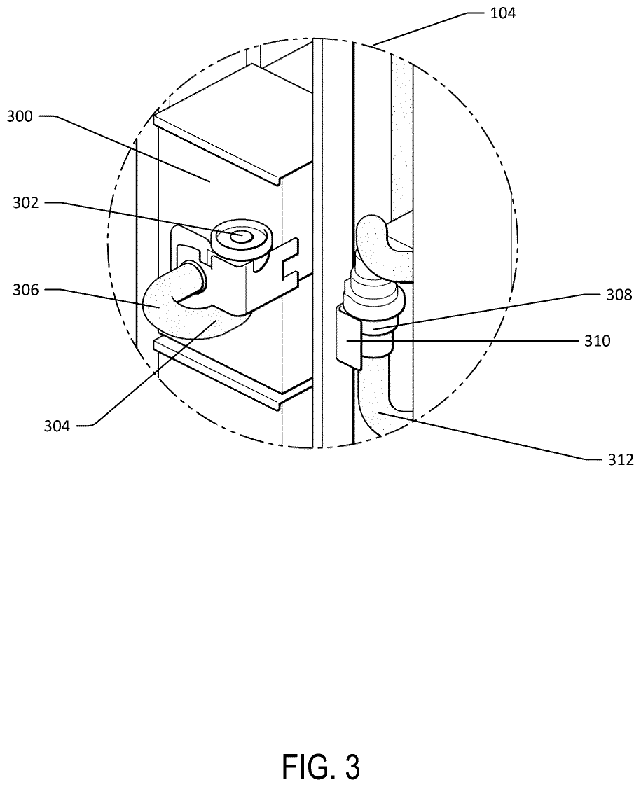

FIG. 3 illustrates an example of the canister 104. Specifically, FIG. 3 illustrates a rear of the canister 104 (e.g., configured to be towards a rear of the server rack 100) including fluid connections thereon. The canister 104 may include a canister frame formed of sheet metal. The canister 104 may contain a rear wall 300 to which various components may be mounted. The rear wall 300 may be intermittent (e.g., have two portions, a left portion and a right portion, or jog). The rear wall 300 may be configured to straddle a center member of the server rack 100 (as shown).

The canister 104 may contain an influent canister QD fitting 302 that is configured to couple with an influent soft manifold QD fitting 208. The influent canister QD fitting 302 may be mounted to the canister 104 (e.g., the rear wall 300) via an influent canister QD bracket 304. The influent canister QD bracket 304 may facilitate easy connection between the influent QD fittings. Coupled with the influent canister QD fitting 302 may be an influent canister hose 306. The influent canister hose 306 may be soft or rigid and is configured to couple the influent canister QD fitting 302 to an influent rigid manifold of the canister 104.

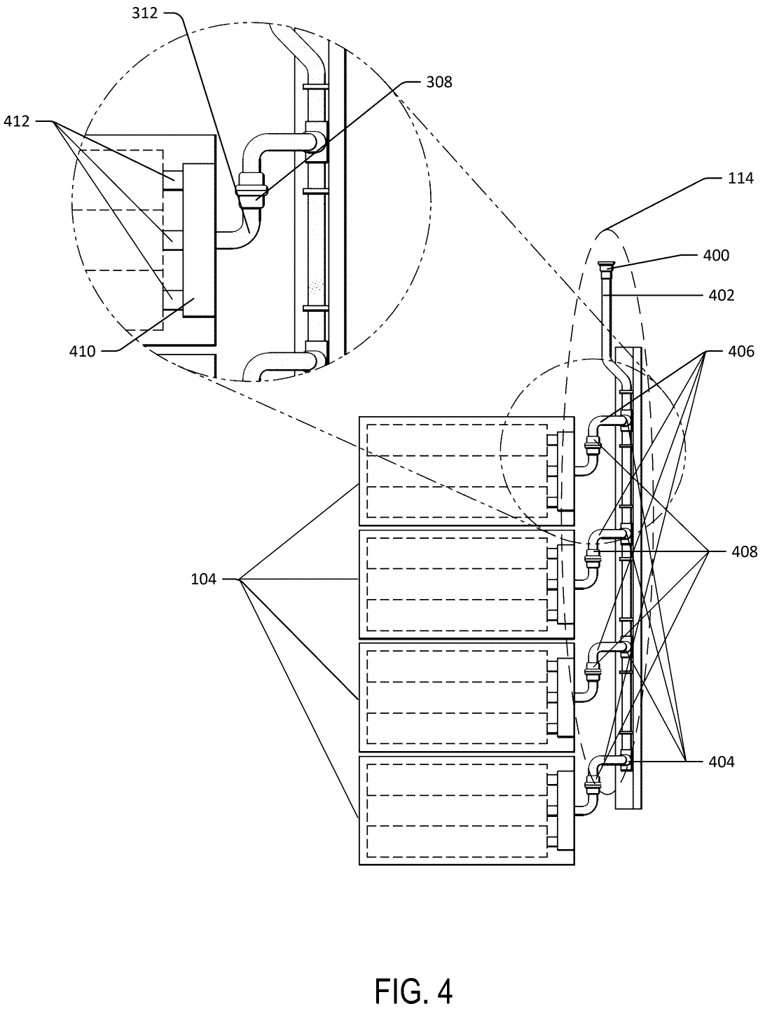

The canister 104 may also contain an effluent canister QD fitting 308 that is configured to couple with an effluent soft manifold QD fitting (shown in FIG. 4). The effluent canister QD fitting 308 may be mounted to the canister 104 (e.g., the rear wall 300) via an effluent canister QD bracket 310. The effluent canister QD bracket 310 may facilitate easy connection between the effluent QD fittings. Coupled with the effluent canister QD fitting 308 may be an effluent canister hose 312. The effluent canister hose 312 may be soft or rigid and is configured to couple the effluent canister QD fitting 308 to an effluent rigid manifold of the canister 104.

In some implementations, the influent soft manifold 108 may be directly coupled with the canister 104 (e.g., an influent hose 206 may be directly coupled with the influent rigid manifold), and/or the effluent soft manifold 114 may be directly coupled with the canister 104 (e.g., an effluent hose of the effluent soft manifold 114 may be directly coupled with the effluent rigid manifold).

### Example Effluent Connections

FIG. 4 illustrates an example of four canisters 104 connected to the effluent soft manifold 114. The effluent soft manifold 114 is shown coupled with the right side 116 of the soft manifold frame 112. To access and/or service the effluent soft manifold 114, the top 118 and the bottom 120 of the soft manifold frame 112 may be removed such that the effluent soft manifold 114 and the right side 116 may be removed from the server rack 100. In the illustrated example, the effluent soft manifold 114 is connected to the canisters 104.

The effluent soft manifold 114 contains an effluent return QD fitting 400 that is configured to attach to a cooling liquid return (e.g., of an infrastructure cooling system). Attached to the effluent return QD fitting 400 is an effluent return 402. The effluent return 402 is configured to collect the cooling liquid from a manifold portion of the effluent soft manifold 114. The effluent return 402 may be coupled with a first of a plurality of effluent branch fittings 404. The effluent branch fittings 404 may be configured to gather the cooling liquid from a plurality of effluent hoses 406. For example, the effluent branch fittings 404 may be tees (pipe or tubing tees). In some implementations, an effluent branch fitting 404 furthest from the effluent return 402 may be an ell. In other implementations, the effluent hoses 406 may all be coupled with the effluent return 402 (e.g., in a multiple (four in the illustrated example)-to-one fitting). At the ends of the effluent hoses 406 are effluent soft manifold QD fittings 408. The effluent soft manifold QD fittings 408 are configured to connect with the effluent canister QD fittings 308 on the canisters 104.

The effluent return 402 and fluid connections between the effluent branch fittings 404 may be soft (e.g., flexible) or rigid. The effluent hoses 406, however, are configured to be soft such that they can move relative to the rest of the effluent soft manifold 114. Soft in the context of this disclosure means the ability to deform, at least slightly, without undue force and/or without breaking. For example, the effluent hoses 406 may be rubber or flexible plastic hose or tubing. The rest of the effluent soft manifold 114 may be formed of rigid pipe or tubing (e.g., metal or plastic), flexible hose or tubing, or some combination thereof. In some implementations, the effluent hoses 406 may be attached to a rigid manifold (e.g., a rigid structure of tubing or piping) of the effluent soft manifold 114. Regardless of how it is constructed, the effluent soft manifold 114 is configured to allow the effluent soft manifold QD fittings 408 to move relative to one another.

As discussed above, the effluent canister hoses 312 are coupled with effluent rigid manifolds 410. The effluent rigid manifolds 410 are attached to the canisters 104 and have a plurality of effluent rigid manifold QD fittings 412 arranged in a fixed orientation. The effluent rigid manifolds 410 may be configurable (relative to the canister 104 and/or relative to itself) for different sized servers.

### Example Rigid Manifold

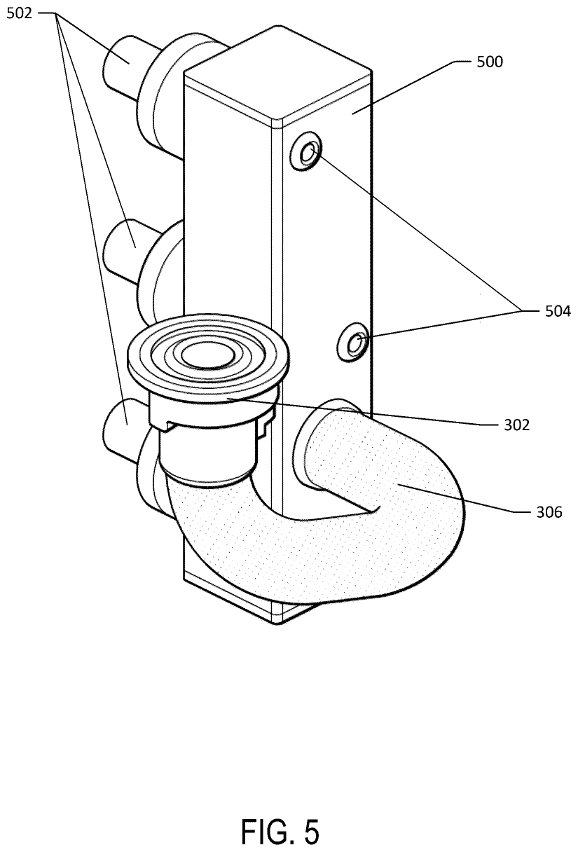

FIG. 5 illustrates an example of an influent rigid manifold 500 and associated components. The effluent rigid manifold 410 (and its associated components) may be configured similarly. The influent rigid manifold 500 may be formed of a single piece (e.g., square tubing) or be a plurality of pieces connected together. For example, the influent rigid manifold 500 may have one or more rotatable portions usable to configure the influent rigid manifold 500 for use with different servers. The influent rigid manifold 500 is rigid, at least in a vertical (e.g., lengthwise) direction, such that a vertical spacing between ports remains constant.

Attached to the influent rigid manifold 500 is a plurality of influent rigid manifold quick-disconnect (QD) fittings 502 (e.g., blind mate fittings). The influent rigid manifold QD fittings 502 are arranged in a fixed configuration (e.g., they are fixed relative to each other in a certain configuration of the influent rigid manifold 500). For example, the influent rigid manifold QD fittings 502 may be arranged in a linear array. In some implementations, the influent rigid manifold 500 may be formed of welded tubes with the influent rigid manifold QD fittings 502 attached to tubing branches of the influent rigid manifold 500.

Coupled with the influent rigid manifold 500 is the influent canister QD fitting 302. The influent canister QD fitting 302 may be coupled to the influent rigid manifold 500 via the influent canister hose 306. In some implementations, the influent canister QD fitting 302 may be rigidly coupled with the influent rigid manifold 500. The influent rigid manifold 500 may also have mounting portions 504 (e.g., threaded holes or rivet nuts) that are configured to facilitate mounting the influent rigid manifold 500 to the canister 104.

The influent rigid manifold 500 (as well as the effluent rigid manifold 410) may be disposed on either side of the rear wall 300. That is, in some implementations, the assembly may be mounted in an interior side of the canister 104 with the influent canister hose 306 (and the effluent canister hose 312) going through the rear wall 300. In other implementations, the assembly may be mounted on an exterior side of the canister 104 with the influent rigid manifold QD fittings 502 (and the effluent rigid manifold QD fittings 412) going through the rear wall 300.

In some implementations, the influent rigid manifold 500 and the effluent rigid manifold 410 may be formed as portions of a single structure (e.g., not separate components). For example, a single rigid manifold may extend across the canister 104 and provide for the influent and effluent fluid connections for the servers.

### Example Canister Mounting

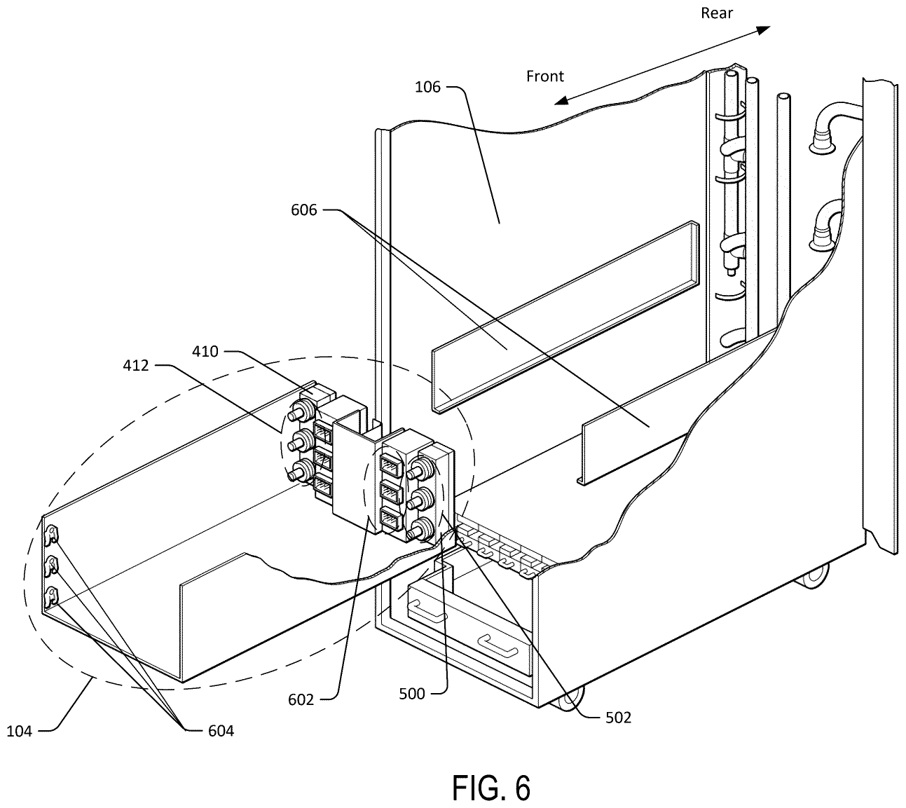

FIG. 6 illustrates an example of the canister 104 and its attachment to the server rack frame 106. The canister 104 includes the influent rigid manifold 500 with the influent rigid manifold QD fittings 502 attached thereto and the effluent rigid manifold 410 with the effluent rigid manifold QD fittings 412 attached thereto. The influent rigid manifold QD fittings 502 and the effluent rigid manifold QD fittings 412 may be oriented towards a front of the canister 104 and be on opposite sides of the canister 104. Furthermore, the influent rigid manifold QD fittings 502 and the effluent rigid manifold QD fittings 412 may be arranged in respective linear arrays that are parallel to one another. To gain access to the fluid connections, a top of the canister 104 may have a multi-piece or hinged lid (not shown). In some implementations, the top of the canister 104 may be easily removed for access. The top of the canister 104 has been removed from the illustration to better shown internal components.

Adjacent to the rigid manifolds may be electrical connections 602 (e.g., one or more per server slot). The electrical connections 602 may provide power and/or communication for the servers within the canister 104. The electrical connections 602 may connect to the server rack frame 106 at a rear of the canister 104.

To support the servers, the canister 104 may contain server portions 604. The server portions 604 (e.g., brackets, shelves, guides, or rollers) are configured to maintain spacing between the servers within the canister 104 and to ensure proper fluid connections with the QD fittings of the canister 104.

The canister 104 is configured to interface with canister portions 606 on the server rack frame 106. The canister portions 606 (e.g., brackets, shelves, guides, or rollers) are configured to support the canister 104 and couple the canister 104 to the server rack frame 106. The canister portions 606 may enable the canister 104 to slide into a front of the server rack frame 106 and may have fixing portions (e.g., screws, threaded holes, or latches) configured to secure the canister 104 to the server rack frame 106.

### Example Canister Mounting

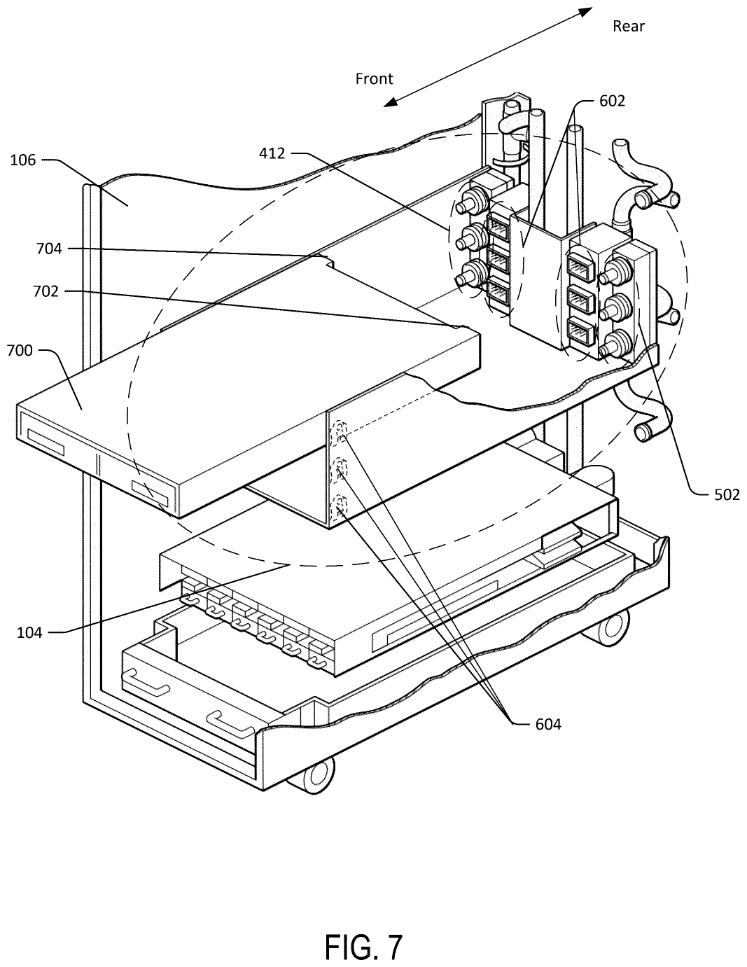

FIG. 7 illustrates an example of a server 700 in relation to the canister 104 while the canister 104 is mounted to the server rack frame 106. The canister 104 may be mounted to the server rack frame 106 prior to having servers 700 installed therein, or the servers 700 may be installed within the canister 104 and the canister 104 with the servers 700 may be installed within the server rack frame 106.

As discussed above, the server 700 may be guided within the canister 104 via the server portions 604. The server 700 may be inserted such that electrical connections are made with the electrical connections 602 (if implemented), an influent server QD fitting 702 connects with one of the influent rigid manifold QD fittings 502, and an effluent server QD fitting 704 connects with one of the effluent rigid manifold QD fittings 412. The QD fittings may be corresponding blind mate fittings (e.g., male on the server 700 and female on the canister 104 or vice-versa). The server 700 may be installed in a front to rear direction and may be secured within the canister 104 using known techniques (e.g., screws, latches, or cams).

In the present disclosure, the terms, “influent” and “effluent,” refer broadly to the flow of a fluid (e.g., the cooling fluid) and corresponding structures. For example, the term “influent” may imply the flow of fluid moving, or arranged to move, into a manifold, pump, line, or other structure, and the term “effluent” may imply the flow of fluid moving, or arranged to move, out of a manifold, pump, line, or other structure. The fluid moving into the structures (e.g., “influent”) may be the same fluid or a different fluid than that moving out of the structures. The terms, “influent” and “effluent,” in some cases, imply the flow of fluid moving, or arranged to move, in a particular direction (e.g., up, down, right, left, forwards, backwards, or the like). Furthermore, these terms may imply the flow of liquid through or across a boundary (e.g., the cooling fluid moving through, into, or out of a pump, manifold, a chamber, a canister, a reservoir, or the like). Structures such as hoses, pipes, manifolds, quick disconnects, blind connectors, pressure fittings, compression fittings, and others facilitate the influent and effluent movement or flows of fluids, as further described in the present disclosure.

### EXAMPLES

Example 1: A canister for coupling a plurality of servers to a server rack, the canister comprising: an influent rigid manifold including a plurality of influent rigid manifold quick-disconnect (QD) fittings arranged in a fixed orientation and configured to couple with influent server QD fittings on the servers; an effluent rigid manifold including a plurality of effluent rigid manifold QD fittings arranged in a fixed orientation and configured to couple with effluent server QD fittings on the servers; an influent canister QD fitting coupled with the influent rigid manifold and configured to couple with an influent soft manifold QD fitting of an influent soft manifold of the server rack; and an effluent canister QD fitting coupled with the effluent rigid manifold and configured to couple with an effluent soft manifold QD fitting of an effluent soft manifold of the server rack.

Example 2: The canister of example 1, wherein the influent rigid manifold and the effluent rigid manifold are formed as portions of a single structure.

Example 3: The canister of example 1, wherein the influent rigid manifold QD fittings and the effluent rigid manifold QD fittings are arranged in respective linear arrays.

Example 4: The canister of example 3, wherein the linear arrays are parallel.

Example 5: The canister of example 1, wherein the influent rigid manifold QD fittings and the effluent rigid manifold QD fittings are blind mate fittings.

Example 6: The canister of example 1, wherein: the canister includes a canister frame; and the influent rigid manifold and the effluent rigid manifold are coupled with the canister frame.

Example 7: The canister of example 6, wherein the canister frame is formed of sheet metal.

Example 8: The canister of example 6, wherein the canister frame is configured to mount to the server rack.

Example 9: The canister of example 6, wherein the canister frame includes server portions configured to orient the servers within the canister.

Example 10: The canister of example 6, wherein: the canister frame includes a rear wall; the influent rigid manifold and the effluent rigid manifold are mounted on an interior side of the rear wall; and the influent canister QD fitting and the effluent canister QD fitting are disposed on an exterior side of the rear wall.

Example 11: The canister of example 6, wherein: the canister frame includes a rear wall; the canister is configured to mount the servers on an interior side of the rear wall; the influent rigid manifold and the effluent rigid manifold are mounted on an exterior side of the rear wall; and the influent rigid manifold QD fittings and the effluent rigid manifold QD fittings go through the rear wall.

Example 12: The canister of example 1, wherein at least one of: the influent canister QD fitting is coupled to the influent rigid manifold via an influent canister hose; or the effluent canister QD fitting is coupled to the effluent rigid manifold via an effluent canister hose.

Example 13: The canister of example 1 wherein at least one of: the influent canister QD fitting is coupled to the canister via an influent canister QD bracket; or the effluent canister QD fitting is coupled to the canister via an effluent canister QD bracket.

Example 14: The canister of example 1, wherein the canister is configured to couple three or more servers to the server rack.

Example 15: The canister of example 1, wherein the canister is configured to receive 19-inch or 21-inch servers.

Example 16: A cooling system for a server rack, the cooling system comprising: an influent soft manifold including: a plurality of influent hoses; and a plurality of influent soft manifold quick-disconnect (QD) fittings at respective ends of the influent hoses; an effluent soft manifold including: a plurality of effluent hoses; and a plurality of effluent soft manifold QD fittings at respective ends of the effluent hoses; and a plurality of canisters configured to couple respective pluralities of servers to the server rack, each canister including: an influent rigid manifold including a plurality of influent rigid manifold QD fittings arranged in a fixed orientation and configured to couple with influent server QD fittings on the servers; an effluent rigid manifold including a plurality of effluent rigid manifold QD fittings arranged in a fixed orientation and configured to couple with effluent server QD fittings on the servers; an influent canister QD fitting coupled with the influent rigid manifold and configured to couple with one of the influent soft manifold QD fittings of the influent soft manifold; and an effluent canister QD fitting coupled with the effluent rigid manifold and configured to couple with one of the effluent soft manifold QD fittings of the effluent soft manifold.

Example 17: The cooling system of example 16, wherein the influent rigid manifold QD fittings and the effluent rigid manifold QD fittings are arranged in respective linear arrays.

Example 18: The cooling system of example 16, wherein each canister includes a canister frame configured to mount to the server rack.

Example 19: The cooling system of example 16, wherein the influent soft manifold and the effluent soft manifold are coupled with a soft manifold frame.

Example 20: A server rack comprising: a server rack frame; an influent soft manifold including: a plurality of influent hoses; and a plurality of influent soft manifold quick-disconnect (QD) fittings at respective ends of the influent hoses; an effluent soft manifold including: a plurality of effluent hoses; and a plurality of effluent soft manifold QD fittings at respective ends of the effluent hoses; and a plurality of canisters configured to be mounted to the server rack frame, each canister configured to couple a plurality of servers to the server rack and including: an influent rigid manifold including a plurality of influent rigid manifold QD fittings arranged in a fixed orientation and configured to couple with influent server QD fittings on the servers; an effluent rigid manifold including a plurality of effluent rigid manifold QD fittings arranged in a fixed orientation and configured to couple with effluent server QD fittings on the servers; an influent canister QD fitting coupled with the influent rigid manifold and configured to couple with one of the influent soft manifold QD fittings of the influent soft manifold; and an effluent canister QD fitting coupled with the effluent rigid manifold and configured to couple with one of the effluent soft manifold QD fittings of the effluent soft manifold.

### Conclusion

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description but is not intended to be exhaustive or limited to this disclosure in the form disclosed. Many modifications and variations will be apparent to those of ordinary skill in the art without departing from the scope and spirit of this disclosure. The various embodiments were chosen and described in order to best explain the principles of this disclosure and the practical application, and to enable others of ordinary skill in the art to understand this disclosure for various embodiments with various modifications as are suited to the particular use contemplated.

What is claimed is:

1. A canister for coupling a plurality of servers to a server rack, the canister comprising:
an influent rigid manifold including a plurality of influent rigid manifold quick-disconnect (QD) fittings arranged in a fixed orientation and configured to couple with influent server QD fittings on the servers;
an effluent rigid manifold including a plurality of effluent rigid manifold QD fittings arranged in a fixed orientation and configured to couple with effluent server QD fittings on the servers;
an influent canister QD fitting coupled with the influent rigid manifold and configured to couple with an influent soft manifold QD fitting of an influent soft manifold of the server rack; and
an effluent canister QD fitting coupled with the effluent rigid manifold and configured to couple with an effluent soft manifold QD fitting of an effluent soft manifold of the server rack.

2. The canister of claim 1, wherein the influent rigid manifold and the effluent rigid manifold are formed as portions of a single structure.

3. The canister of claim 1, wherein the influent rigid manifold QD fittings and the effluent rigid manifold QD fittings are arranged in respective linear arrays.

4. The canister of claim 3, wherein the linear arrays are parallel.

5. The canister of claim 1, wherein the influent rigid manifold QD fittings and the effluent rigid manifold QD fittings are blind mate fittings.

6. The canister of claim 1, wherein:
the canister includes a canister frame; and
the influent rigid manifold and the effluent rigid manifold are coupled with the canister frame.

7. The canister of claim 6, wherein the canister frame is formed of sheet metal.

8. The canister of claim 6, wherein the canister frame is configured to mount to the server rack.

9. The canister of claim 6, wherein the canister frame includes server portions configured to orient the servers within the canister.

10. The canister of claim 6, wherein:
the canister frame includes a rear wall;
the influent rigid manifold and the effluent rigid manifold are mounted on an interior side of the rear wall; and
the influent canister QD fitting and the effluent canister QD fitting are disposed on an exterior side of the rear wall.

11. The canister of claim 6, wherein:
the canister frame includes a rear wall;
the canister is configured to mount the servers on an interior side of the rear wall;
the influent rigid manifold and the effluent rigid manifold are mounted on an exterior side of the rear wall; and
the influent rigid manifold QD fittings and the effluent rigid manifold QD fittings go through the rear wall.

12. The canister of claim 1, wherein at least one of:
the influent canister QD fitting is coupled to the influent rigid manifold via an influent canister hose; or
the effluent canister QD fitting is coupled to the effluent rigid manifold via an effluent canister hose.

13. The canister of claim 1 wherein at least one of:
the influent canister QD fitting is coupled to the canister via an influent canister QD bracket; or
the effluent canister QD fitting is coupled to the canister via an effluent canister QD bracket.

14. The canister of claim 1, wherein the canister is configured to couple three or more servers to the server rack.

15. The canister of claim 1, wherein the canister is configured to receive 19 inch or 21 inch servers.

16. A cooling system for a server rack, the cooling system comprising:
an influent soft manifold including:
a plurality of influent hoses; and
a plurality of influent soft manifold quick-disconnect (QD) fittings at respective ends of the influent hoses;
an effluent soft manifold including:
a plurality of effluent hoses; and
a plurality of effluent soft manifold QD fittings at respective ends of the effluent hoses; and
a plurality of canisters configured to couple respective pluralities of servers to the server rack, each canister including:
an influent rigid manifold including a plurality of influent rigid manifold QD fittings arranged in a fixed orientation and configured to couple with influent server QD fittings on the servers;
an effluent rigid manifold including a plurality of effluent rigid manifold QD fittings arranged in a fixed orientation and configured to couple with effluent server QD fittings on the servers;
an influent canister QD fitting coupled with the influent rigid manifold and configured to couple with one of the influent soft manifold QD fittings of the influent soft manifold; and
an effluent canister QD fitting coupled with the effluent rigid manifold and configured to couple with one of the effluent soft manifold QD fittings of the effluent soft manifold.

17. The cooling system of claim 16, wherein the influent rigid manifold QD fittings and the effluent rigid manifold QD fittings are arranged in respective linear arrays.

18. The cooling system of claim 16, wherein each canister includes a canister frame configured to mount to the server rack.

19. The cooling system of claim 16, wherein the influent soft manifold and the effluent soft manifold are coupled with a soft manifold frame.

20. A server rack comprising:
a server rack frame;
an influent soft manifold including:
a plurality of influent hoses; and
a plurality of influent soft manifold quick-disconnect (QD) fittings at respective ends of the influent hoses;
an effluent soft manifold including:
a plurality of effluent hoses; and
a plurality of effluent soft manifold QD fittings at respective ends of the effluent hoses; and
a plurality of canisters configured to be mounted to the server rack frame, each canister configured to couple a plurality of servers to the server rack and including:
an influent rigid manifold including a plurality of influent rigid manifold QD fittings arranged in a fixed orientation and configured to couple with influent server QD fittings on the servers;
an effluent rigid manifold including a plurality of effluent rigid manifold QD fittings arranged in a fixed orientation and configured to couple with effluent server QD fittings on the servers;
an influent canister QD fitting coupled with the influent rigid manifold and configured to couple with one of the influent soft manifold QD fittings of the influent soft manifold; and
an effluent canister QD fitting coupled with the effluent rigid manifold and configured to couple with one of the effluent soft manifold QD fittings of the effluent soft manifold.
